(19) United States
(12) Patent Application Publication
(10) Pub. No.: US 2005/0275090 A1
(43) Pub. Date: Dec. 15, 2005

(54) Chip-component-mounted device and semiconductor device

(75) Inventor: Taibo Nakazawa, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC COMPOUND SEMICONDUCTOR DEVICES, LTD.

(21) Appl. No.: 11/147,158

(22) Filed: Jun. 8, 2005

(30) Foreign Application Priority Data
Jun. 9, 2004 (JP) 2004-171049

(51) Int. Cl. H01L 23/48

(52) U.S. Cl. 257/730; 257/782

(57) ABSTRACT

A chip-component-mounted device comprises a print wiring board or lead frame, an electrically conductive adhesive and a chip component, said chip component being mounted on said print wiring board or lead frame through said electrically conductive adhesive, said chip component having a corner part, a ridgeline of said corner part facing a connected part side of said print wiring board or lead frame, an angle made by a face adjacent to said ridgeline and a face of said connected part being acute.

### FIELD OF THE INVENTION

The present invention relates to a chip-component-mounted device and semiconductor device in which a chip component is mounted on a print wiring board or lead frame, and, particularly, to a chip-component-mounted device and semiconductor device which can prevent a short circuit with an adjacent pad (or lead) and component.

### BACKGROUND OF THE INVENTION

In recent years, a semiconductor device in which a semiconductor element is mounted on a print wiring board (or lead frame) is becoming higher in density, and there is an increasing importance of a semiconductor device of a module type, in which a chip component is mounted. The chip component, such as a bypass condenser for stabilization of power source, a condenser for stabilization of circuit operation, a load resistance, an inductance or the like, is disposed around the semiconductor element. In most of the semiconductor devices of the module type, the semiconductor element and chip component are mounted on the print wiring board (or lead frame) and sealed by a resin collectively. Solder or an electrically conductive adhesive is used for electrical connection between the semiconductor element and chip component and the print wiring board.

When the semiconductor device in which solder such as SnPb, SnAgCu and so like is used is mounted on a mother board, heat generated in the mounting may fuse the solder in the semiconductor device. If the solder in the semiconductor device is fused, thermal expansion of the fused solder may cause a crack in the sealing resin, and outflow of the solder along the crack may cause a short circuit between pad (or leads). The electrically conductive adhesive is therefore being used widely.

A conventional example in which the electrically conductive adhesive is used is explained below using drawings. FIG. 5 is a partial perspective view schematically showing a structure of a chip-component-mounted device according to a conventional example. FIG. 6 is a partially cross-sectional view schematically showing a structure of a chip-component-mounted device according to a conventional example. A chip component 102 is mounted on a pad 101a of a print wiring board 101, with a flat part of the chip component 102 facing downward. An electrode part 102a of the chip component 102 is physically and electrically connected to the pad 101a of the print wiring board 101 through an electrically conductive adhesive 103. The pad 101a of the print wiring board 101 comprises plating of noble metal such as Au. The electrode part 102a of the chip component 101 comprises plating of noble metal such as AgPd or Ag. Most of the electrically conductive adhesives 103 include metal filler such as Ag in an epoxy resin adhesive.

### SUMMARY OF THE DISCLOSURE

When the electrically conductive adhesive 103 is used, it is necessary to pay sufficient attention to the connection reliability because of its weaker connection strength than the solder. If the connection strength is weak, impact during an assembly process (for example, a wire bonding step or resin sealing step) after mounting the chip component 102 or a temperature change (for example, reflowing) around a product after finishing the assembly may break off the electrical connection of the electrode part 102a of the chip component 102 with the pad 101a of the print wiring board 101 (or a lead on a lead frame) or may bring about a greater electrical resistance because of deterioration of the strength of the connected part.

Since the connection strength of the electrically conductive adhesive 103 is weaker than the connection strength of the solder, the connection reliability of the electrically conductive adhesive 103 decreases as compared with the connection reliability of the solder. In order to improve the connection strength, it is necessary to increase the quantity of the electrically conductive adhesive 103 to enlarge the contact area of the chip component 102 with the electrically conductive adhesive 103.

### [Patent Document 1]

JP Patent Kokai Publication No. P2002-25801A

When the quantity of the electrically conductive adhesive is increased to enlarge the contact area of the chip component with the electrically conductive adhesive, the following problems arise.

A first problem resides in that the area of application of the electrically conductive adhesive is enlarged and that there is therefore a probability that the electrically conductive adhesive short-circuits with the adjacent pad (or lead) or component.

A second problem resides in that the area of application of the electrically adhesive is enlarged and that there is therefore a probability that the electrically conductive adhesive flows over the lead to reach the back side of the lead when the chip component is mounted on a lead frame. If the electrically conductive adhesive goes to the back side of the lead, a conveyor for a component mounting apparatus is contaminated, and there is a therefore probability that the electrically conductive adhesive adheres to the back side of a product carried later and to an area where a mold presses down upon resin sealing with a mold. Moreover, if the electrically conductive adhesive adhered to the back side of the lead frame is hardened, a bonding face becomes out of the horizontal in a later bonding step, and thus there is a probability of a poor bonding. Further, if the electrically conductive adhesive adhered to the area where the mold presses down during the resin sealing with the mold is hardened, a gap is formed between the mold and the lead frame, and thus there is a probability that the sealing resin leaks out and that the mold or sealing apparatus is damaged.

Therefore, there is much to be desired in the art for a chip-component-mounted device and semiconductor device which can prevent a short circuit between an electrically conductive adhesive and an adjacent pad (or lead) or component even if the quantity of the electrically conductive adhesive is increased and the contact area of the chip component with the electrically conductive adhesive is enlarged.

Also, there is much to be desired in the art for a chip-component-mounted device and semiconductor device which can prevent the electrically conductive adhesive from going to the back side of the lead even if the contact area of the chip component with the electrically conductive adhesive is enlarged.

In a first aspect of the present invention, a chip-component-mounted device comprises a print wiring board or lead frame, an electrically conductive adhesive and a chip component. The chip component is mounted on the print wiring board or lead frame through the electrically conductive adhesive. The chip component has a corner part. A ridgeline of the corner part faces to a connected part side of the print wiring board or lead frame. An angle made by a face adjacent to the ridgeline and a face of the connected part is acute.

In a second aspect of the present invention, a chip-component-mounted device comprises a print wiring board or lead frame, an electrically conductive adhesive and a chip component. The chip component is mounted on the print wiring board or lead frame through the electrically conductive adhesive. The chip component has a corner part. A ridgeline of the corner part faces to a connected part side of the print wiring board or lead frame. An angle made by a face adjacent to the ridgeline and a face of the connected part is acute. The face of the connected part has a groove along a direction of the ridgeline. The corner part of the chip component is put in the groove.

In a third aspect of the present invention, a semiconductor device comprises a chip-component-mounted device and a semiconductor element. The chip-component-mounted device comprises a print wiring board or lead frame, an electrically conductive adhesive and a chip component. The chip component is mounted on the print wiring board or lead frame through the electrically conductive adhesive. The chip component has a corner part. A ridgeline of the corner part faces to a connected part side of the print wiring board or lead frame. An angle made by a face adjacent to the ridgeline and a face of the connected part is acute. The semiconductor element is mounted on the chip-component-mounted device.

In a fourth aspect of the present invention, a semiconductor device comprises a chip-component-mounted device and a semiconductor element. The chip-component-mounted device comprises a print wiring board or lead frame, an electrically conductive adhesive and a chip component. The chip component is mounted on the print wiring board or lead frame through the electrically conductive adhesive. The chip component has a corner part. A contour (ridgeline) of the corner part faces a connected part side of the print wiring board or lead frame. An angle generated by a face adjacent to the ridgeline and a face of the connected part is acute. The face of the connected part has a groove along a direction of the edge (ridgeline). The corner part of the chip component is disposed in the groove. The semiconductor element is mounted on the chip-component-mounted device.

The meritorious effects of the present invention are summarized as follows.

According to the present invention (claims 1 to 4), a possibility that the electrically conductive adhesive short-circuits with an adjacent pad or component could reduce because the electrically conductive adhesive is prevented from extending toward the perpendicular direction to the ridgeline of the corner part of the chip member even if the quantity of the electrically conductive adhesive is increased as compared with a conventional structure to enlarge the contact area of the chip component with the electrically conductive adhesive and therefore to increase the connection strength.

According to the present invention (claims 1 to 4), similarly, when the chip component is mounted on a lead frame, a possibility that the electrically conductive adhesive flows over the lead and goes to the back side of the lead also could reduce because the electrically conductive adhesive is prevented from extending toward the perpendicular direction to the ridgeline of the corner part of the chip member.

According to the present invention (claim 2), the connection strength could increase further because the groove part increases the contact area of the electrically conductive adhesive with a connected part (the pad of the print wiring board, the lead of the lead frame) and generates an anchor effect. Moreover, the position and inclination of the chip component could be stabilized and the connection strength therefore could be stabilized because the groove part also keeps the angle formed by the connected part and the chip component even if the strength to keep a form before hardening of the electrically conductive adhesive is insufficient.

### BRIEF DESCRIPTION OF THE DRAWINGS

FIG. 1 is a partially perspective view schematically showing a structure of a chip-component-mounted device according to a first embodiment of the present invention.

FIG. 2 is a partially cross-sectional view schematically showing a structure of a chip-component-mounted device according to a first embodiment of the present invention.

FIG. 3 is a partially perspective view schematically showing a structure of a chip-component-mounted device according to a second embodiment of the present invention.

FIG. 4 is a partially cross-sectional view schematically showing a structure of a chip-component-mounted device according to a second embodiment of the present invention.

FIG. 5 is a partially perspective view schematically showing a structure of a chip-component-mounted device according to a conventional example.

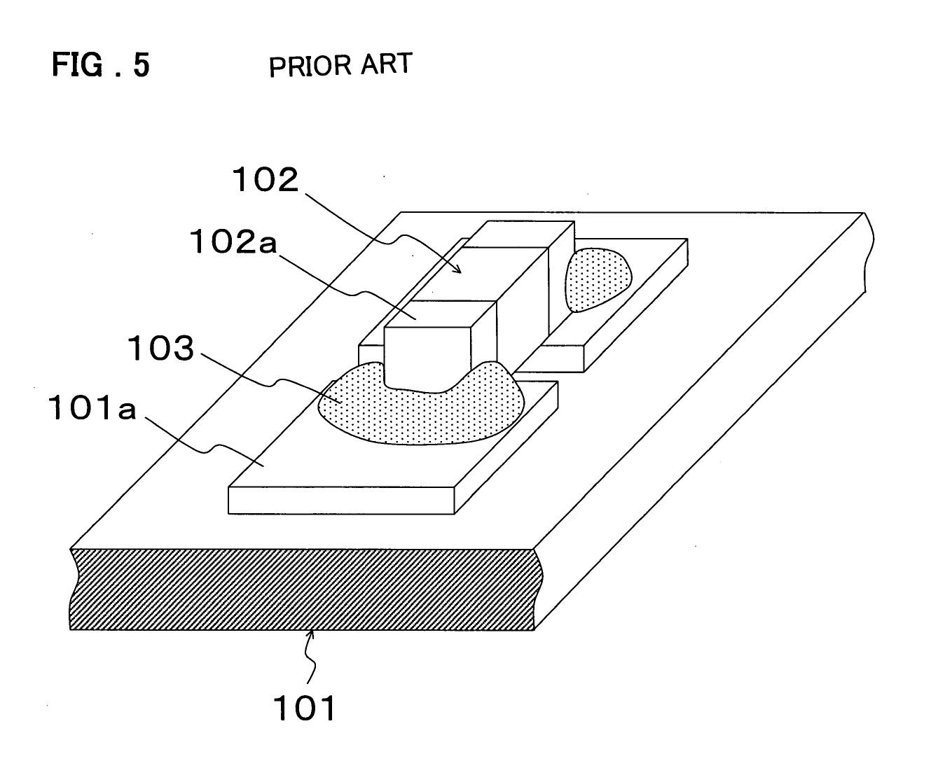

FIG. 6 is a partially cross-sectional view schematically showing a structure of a chip-component-mounted device according to a conventional example.

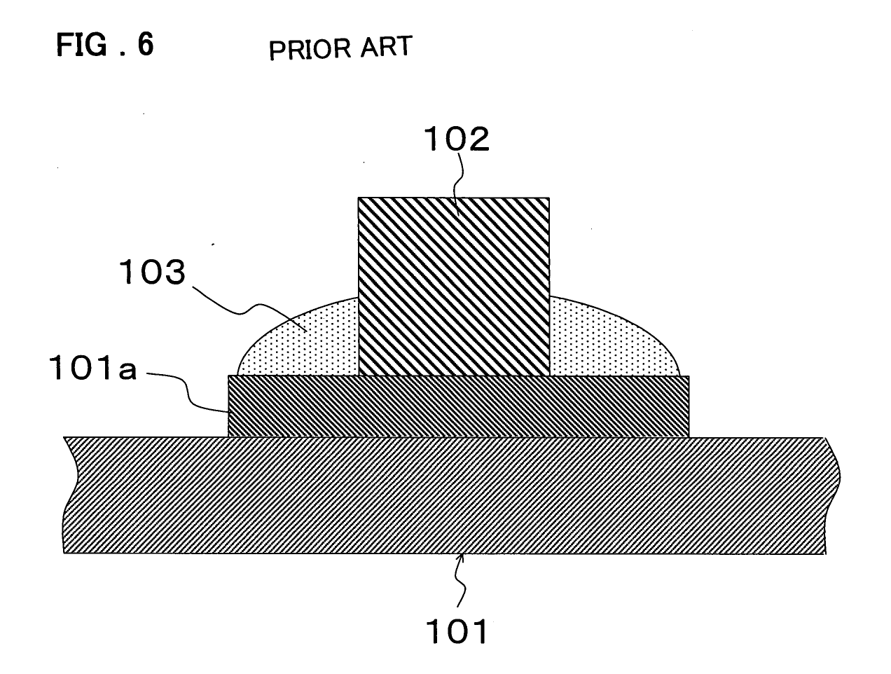

### PREFERRED EMBODIMENTS OF THE INVENTION

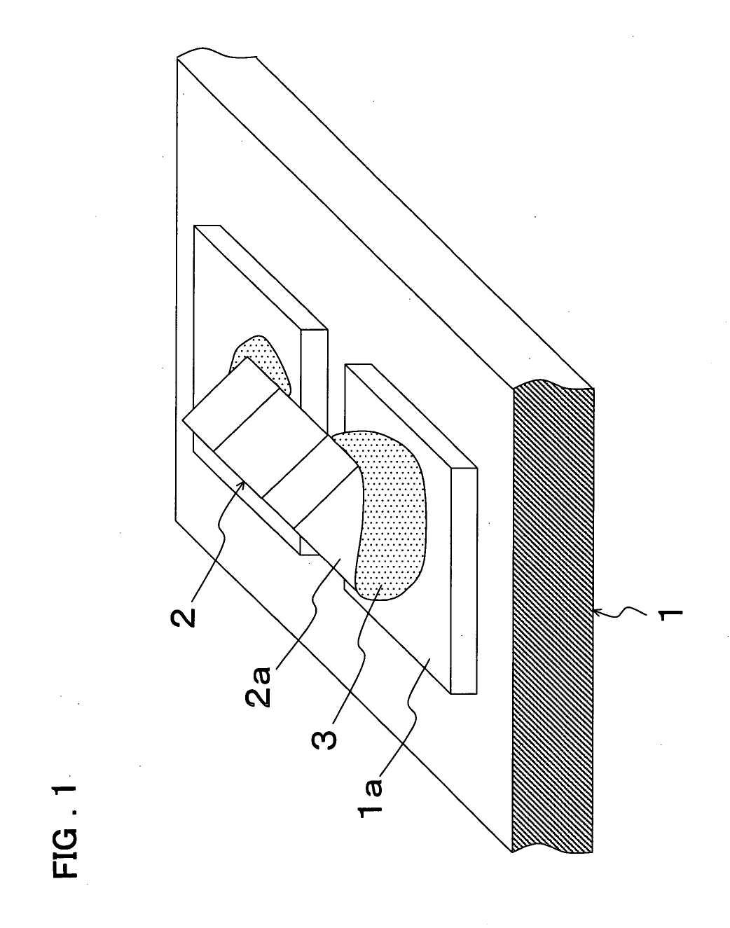

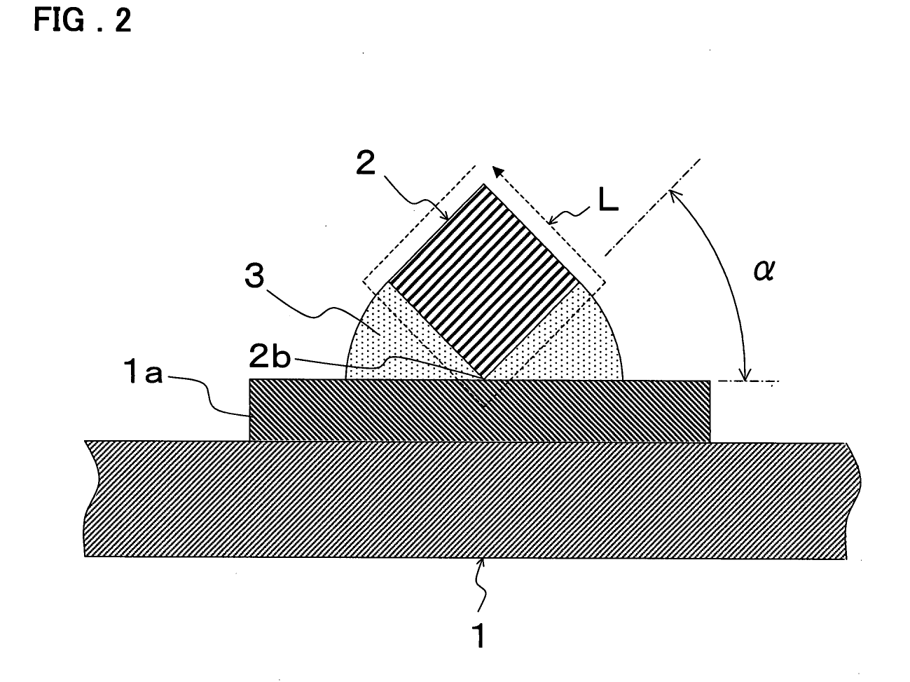

A chip-component-mounted device according to a first embodiment of the present invention is explained below with reference to drawings. FIG. 1 is a partially perspective view schematically showing a structure of the chip-component-mounted device according to the first embodiment of the present invention. FIG. 2 is a partially cross-sectional view schematically showing a structure of the chip-component-mounted device according to the first embodiment of the present invention.

In the first embodiment, a chip component 2 is arranged on two pads 1a (connected parts) of a print wiring board 1, on which a semiconductor element (not shown) is mounted, so as to bridge between two pads 1a, a corner part 2b of the chip component 2 facing toward the pad 1a side. The pad 1a and an electrode part 2a corresponding to the pad 1a are connected each other through an electrically conductive adhesive 3 physically and electrically. The pad 1a of the print wiring board 1 is an electrically conductive pad formed on a surface of a wiring (not shown) in the print wiring board 1 and comprises plating of noble metal such as Au. The other (corresponding) pad 1a is arranged leaving a predetermined space from the pad 14 shown on the front side. The chip component 2 is an electronic component, such as a condenser, a resistance, an inductance or the like, like a chip, comprising at least the corner part (or edge) 2b and also comprises the electrode parts 2a on both the ends. The electrode 2a of the chip component 2 comprises plating of noble metal such as AgPd, Ag or the like. Most of the electrically conductive adhesives 3 include metal filler such as Ag in an epoxy resin adhesive. An angle a made by a face of the pad 1a and a face adjacent to a ridgeline of the corner part 2b of the chip component 2 is acute (see FIG. 2). It does not matter whether or not the corner part 2b of the chip component 2 touches the face of the pad 1a.

The electrically conductive adhesive 3 is filled at least between the pad 1a and the electrode part 2a. The contact area of the chip component 2 with the electrically conductive adhesive 3 amounts to about 50% of a length L of the circumference of the chip component 2 as viewed in the cross section, which is considered to be sufficient to secure connection reliability of the pad 1a of the print wiring board 1 with the chip component 2 (see FIG. 2).

According to the first embodiment, the connection strength of the pad 1a of the print wiring board with the chip component 2 becomes sufficiently large, and the electrically conductive adhesive 3 does not cause the short-circuit with the adjacent pad and component at all. The reason is that the electrically conductive adhesive 3 is filled between the pad 1a of the print wiring board 1 and the electrode part 2a of the chip component 2 and is therefore prevented from extending toward a perpendicular direction to the ridgeline of the corner part 2b of the chip component 2 even if the quantity of the electrically conductive adhesive 3 is increased and accounts for about 50% of the length L of the circumference of the chip component 2.

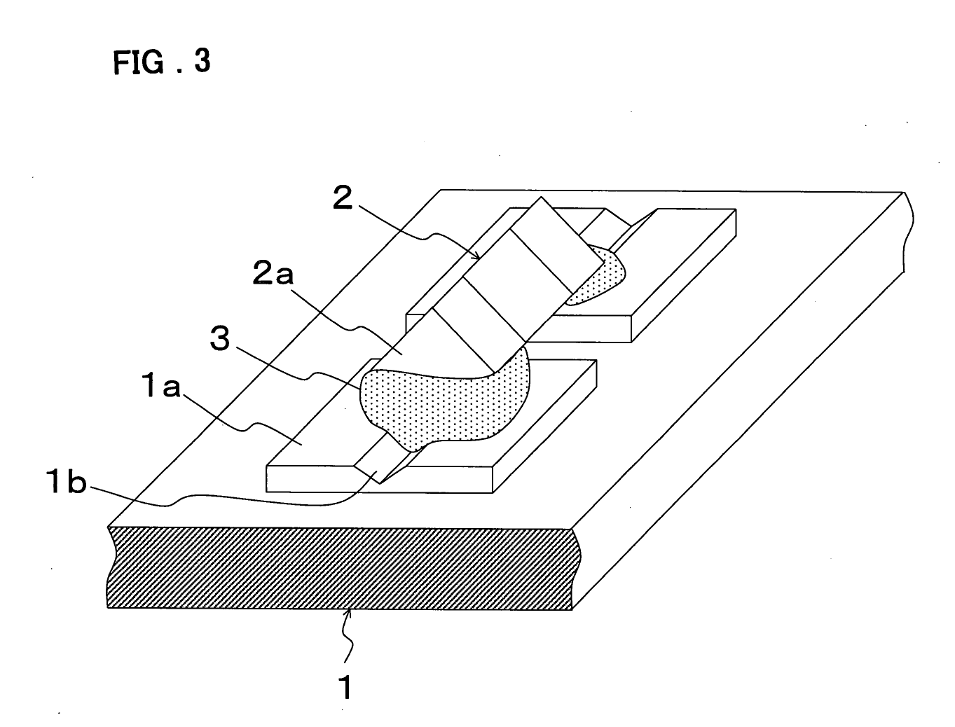

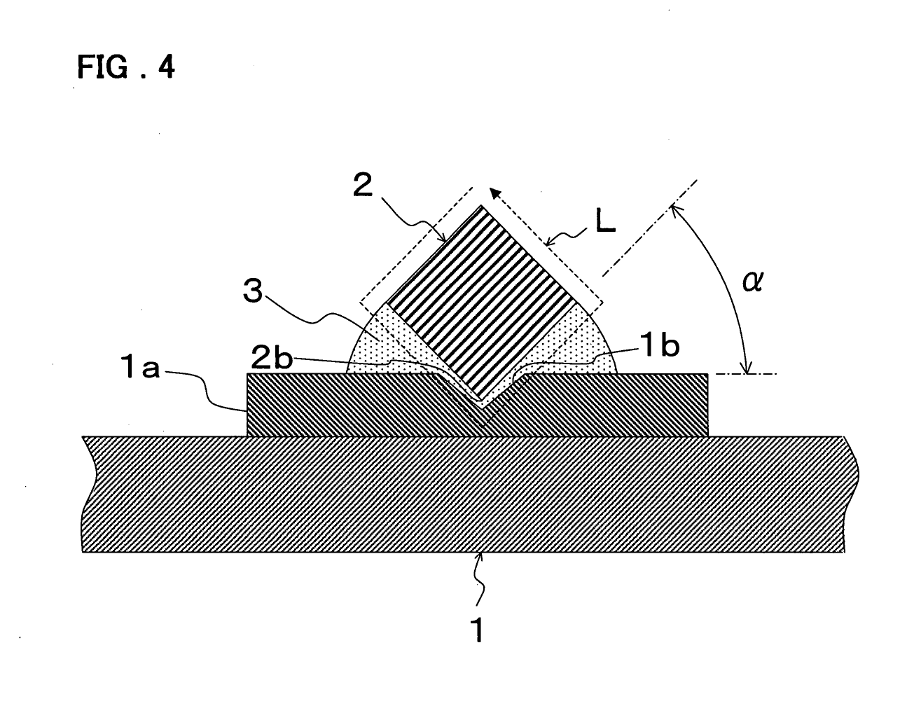

Next, a chip-component-mounted device according to a second embodiment of the present invention is explained below using drawings. FIG. 3 is a partially perspective view schematically showing a structure of the chip-component-mounted device according to the second embodiment of the present invention. FIG. 4 is a partial cross-sectional view schematically showing a structure of the chip-component-mounted device according to the second embodiment of the present invention.

In the second embodiment, as the first embodiment, the chip component 2 is mounted on two pads 1a (connected parts) of the print wiring board 1, on which the semiconductor element (not shown) is mounted, such that the chip component 2 bridges between two pads 1a and that the corner part 2b of the chip component 2 faces toward the pad 1a side. The pad 1a and the corresponding electrode part 2a are connected each other through the electrically conductive adhesive 3 physically and electrically. The pad 1a of the print wiring board 1 is an electrically conductive pad formed on the surface of the wiring (not shown) of the print wiring board 1 and comprises the plating of noble metal such as Au. The other (corresponding) pad 1a is arranged leaving from the pad 1a. The chip component 2 is an electronic component, such as a condenser, a resistance, an inductance or the like, like a chip (for example, a rectangular parallelepiped or a cube), comprising at least the corner part 2b and also comprises the electrode parts 2a on both the ends. The electrode 2a of the chip component 2 comprises a plating of noble metal such as AgPd, Ag or the like. An adhesive, for example, including a metal filler, such as Ag, in an epoxy resin adhesive is used as the electrically conductive adhesive 3. An angle [symbol] made by the face of the pad 1a and the face adjacent to the ridgeline of the corner part 2b of the chip component 2 is acute (see FIG. 4). It does not matter whether or not the corner part 2b of the chip component 2 touches the face of the pad 1a.

The difference between the second embodiment and the first embodiment is that a groove part 1b is formed along the ridgeline direction of the corner part 2b of the chip component 2 on the face of the pad 1a of the print wiring board 1. The groove part 1b shown in FIG. 4 is V-shaped, but may be an arc or rectangle in shape or other shapes. The corner part 2b of the chip component 2 is disposed in the groove part 1b, and the electrically conductive adhesive 3 is also filled between the corner part 2b and the groove part 1b.

The electrically conductive adhesive 3 is filled at least between the pad 1a and the electrode part 2a. The contact area of the chip component 2 with the electrically conductive adhesive 3 accounts for about 50% of the length L of the circumference of the chip component 2 in view of the sectional direction, which is considered to be sufficient to secure connection reliability of the pad 1a of the print wiring board 1 with the chip component 2 (see FIG. 4).

According to the second embodiment, the connection of the pad 1a of the print wiring board 1 with the chip component 2 is sufficiently strong, and the electrically conductive adhesive 3 does not short-circuit with the adjacent pad and component at all. The reason is that the electrically conductive adhesive 3 is filled between the pad 1a of the print wiring board 1 and the electrode part 2a of the chip component 2 and is therefore prevented from extending toward a perpendicular direction to the ridgeline of the corner part 2b of the chip component 2 even if the quantity of the electrically conductive adhesive 3 is increased and amounts to about 50% of the length L of the circumference of the chip component 2. In addition, the groove 1b increases the contact area of the electrically conductive adhesive 3 with the pad 1a of the print wiring board 1 and generates an anchor effect, thereby making the connection stronger than the first embodiment. Even if the strength to keep the form before hardening of the electrically conductive adhesive 3 is insufficient, the groove 1b can keep the angle [symbol] made by the pad 1a of the print wiring board 1 and the chip component 2, the position and inclination of the chip component 2 is therefore stabilized, and the connection strength is also stabilized.

Next, a third embodiment is explained. In the first and second embodiments, the chip component mounted on the print wiring board is explained, whereas, in the third embodiment, a lead frame is used in place of the print wiring board. When the chip component is mounted on the lead frame, the ridgeline of the corner part (corresponding to 2b in FIG. 2 or 4) of the chip component (corresponding to 2 in FIG. 1 or 3) faces a lead (a connected part; corresponding to 1a in FIG. 1 or 3) side of the lead frame. The lead of the lead frame and the electrode part (corresponding to 2a in FIG. 1 or 3) of the corresponding chip component are connected each other through the electrically conductive adhesive (corresponding to 3 in FIG. 1 or 3) physically and electrically. According to the third embodiment, an effect similar to the effect of the first or second embodiment is obtained, and a possibility that the electrically conductive adhesive goes to the back side of the lead reduces.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

1. A chip-component-mounted device comprising:
a print wiring board or lead frame; an electrically conductive adhesive; and a chip component;
wherein said chip component is mounted on said print wiring board or lead frame through said electrically conductive adhesive,
said chip component has a corner part,
a ridgeline of said corner part faces a connected part side of said print wiring board or lead frame, and
an angle made by a face adjacent to said ridgeline and a face of said connected part is acute.

2. A chip-component-mounted device comprising:
a print wiring board or lead frame; an electrically conductive adhesive; and a chip component;
wherein said chip component is mounted on said print wiring board or lead frame through said electrically conductive adhesive,
said chip component has a corner part,
a ridgeline of said corner part faces a connected part side of said print wiring board or lead frame,
an angle made by a face adjacent to said ridgeline and a face of said connected part is acute,
said face of said connected part has a groove along a direction of said ridgeline, and
said corner part of said chip component is disposed in said groove.

3. A semiconductor device comprising:
a chip-component-mounted device and a semiconductor element;
wherein said chip-component-mounted device comprises ones defined in claim 1.

4. A semiconductor device comprising:
a chip-component-mounted device and a semiconductor element;
wherein said chip-component-mounted device comprises ones defined in claim 2.

5. The chip-component-mounted device as defined in claim 1,
wherein said print wiring board has a plurality of said connected parts,
said connected parts are electrically conductive pads formed on a surface of a wiring of said print wiring board and comprising plaiting of noble metal and are arranged leaving a predetermined space between the connected parts, and
said chip component is an electronic component, comprises a plurality of electrodes, each comprising plating of noble metal, and is arranged so as to bridge said connected parts.

6. The chip-component-mounted device as defined in claim 2,
wherein said print wiring board has a plurality of said connected parts,
said connected parts are electrically conductive pads formed on a surface of a wiring of said print wiring board and comprising plaiting of noble metal and are arranged leaving a predetermined space between the connected parts, and
said chip component is an electronic component, comprises a plurality of electrodes, each comprising plating of noble metal, and is arranged so as to bridge said connected parts.

7. The semiconductor device as defined in claim 3,
wherein said print wiring board has a plurality of said connected parts,
said connected parts are electrically conductive pads formed on a surface of a wiring of said print wiring board and comprising plaiting of noble metal and are arranged leaving a predetermined space between the connected parts, and
said chip component is an electronic component, comprises a plurality of electrodes, each comprising plating of noble metal, and is arranged so as to bridge said connected parts.

8. The semiconductor device as defined in claim 4,
wherein said print wiring board has a plurality of said connected parts,
said connected parts are electrically conductive pads formed on a surface of a wiring of said print wiring board and comprising plaiting of noble metal and are arrayed leaving a predetermined space between the connected parts, and
said chip component is an electronic component, comprises a plurality of electrodes, each comprising plating of noble metal, and is arranged so as to bridge said connected parts.

9. The chip-component-mounted device as defined in claim 1,
wherein said electrically conductive adhesive includes metal filler.

10. The chip-component-mounted device as defined in claim 2,
wherein said electrically conductive adhesive includes metal filler.

11. The chip-component-mounted device as defined in claim 1,
wherein a contact area of said chip component with said electrically conductive adhesive accounts for about 50% of a length of the circumference of said chip component as viewed in a cross section.

12. The chip-component-mounted device as defined in claim 2,
wherein a contact area of said chip component with said electrically conductive adhesive accounts for about 50% of a length of the circumference of said chip component as viewed in a cross section.

13. The semiconductor device as defined in claim 3,
wherein a contact area of said chip component with said electrically conductive adhesive accounts for about 50% of a length of the circumference of said chip component as viewed in a cross section.

14. The semiconductor device as defined in claim 4,
wherein a contact area of said chip component with said electrically conductive adhesive accounts for about 50% of a length of the circumference of said chip component as viewed in a cross section.

15. The chip-component-mounted device as defined in claim 2,
wherein said electrically conductive adhesive is filled between said corner part and said groove.

16. The semiconductor device as defined in claim 4,
wherein said electrically conductive adhesive is filled between said corner part and said groove.

17. The chip-component-mounted device as defined in claim 2,
wherein said groove is V-shaped, arc or rectangular in shape.

18. The semiconductor device as defined in claim 4,
wherein said groove is V-shaped, arc or rectangular in shape.
